(19) United States
(12) Patent Application Publication
(10) Pub. No.: US 2026/0297728 A1
(43) Pub. Date: Oct. 1, 2026

(54) FILM FORMATION METHOD AND FILM FORMATION APPARATUS

(71) Applicant: Tokyo Electron Limited, Tokyo (JP)

(72) Inventor: Kazuki DEMPOH, Nirasaki-shi (JP)

(21) Appl. No.: 19/703,163

(22) Filed: Jun. 10, 2026

Related U.S. Application Data
(63) Continuation of application No. 17/906,353, filed on Mar. 2, 2021.

(30) Foreign Application Priority Data
Mar. 16, 2020 (JP) 2020-045257

(51) Int. Cl. C23C 16/02; C23C 16/04; C23C 16/455; C23C 16/507; H10P 14/42

(52) U.S. Cl. CPC C23C 16/0263; C23C 16/047; C23C 16/455; C23C 16/507; H10P 14/42

(57) ABSTRACT

A film formation method according to one aspect of the present disclosure includes: a first step of irradiating a substrate, on which a recess is formed, with an electron beam; a second step of supplying a raw material gas to the substrate and allowing the raw material gas to be adsorbed on a bottom surface of the recess; and a third step of supplying hydrogen radicals to the substrate and allowing the raw material gas adsorbed on the bottom surface of the recess to react with the hydrogen radicals.

### CROSS-REFERENCE TO RELATED APPLICATIONS

The present application is a continuation of U.S. patent application Ser. No. 17/906,353, filed Sep. 15, 2022, which is a U.S. National Stage Entry of International Patent Application No. PCT/JP2021/007903, filed Mar. 2, 2021, which claims the benefit of priority to Japanese Patent Application No. 2020-045257, filed Mar. 16, 2020, each of which is hereby incorporated herein by reference in its entirety.

### TECHNICAL FIELD

The present disclosure relates to a film formation method and a film formation apparatus.

### BACKGROUND

In the related art, a technique for forming a metal film in a recess formed on a substrate such as a semiconductor wafer (hereinafter, also referred to as a wafer) is known (see Patent Document 1).

### PRIOR ART DOCUMENT

### Patent Document

Patent Document 1: Japanese Laid-Open Patent Publication No. H06-252053

### SUMMARY

The present disclosure provides a technique capable of selectively forming a metal film on a bottom surface of a recess formed in a substrate.

A film formation method according to one aspect of the present disclosure includes a first step, a second step, and a third step. In the first step, a substrate on which a recess is formed is irradiated with an electron beam. In the second step, a raw material gas is supplied to the substrate, and the raw material gas is adsorbed on a bottom surface of the recess. In the third step, hydrogen radicals are supplied to the substrate to allow the raw material gas adsorbed on the bottom surface of the recess to react with the hydrogen radicals.

According to the present disclosure, it is possible to selectively form a metal film on a bottom surface of a recess formed in a substrate.

### BRIEF DESCRIPTION OF DRAWINGS

FIG. 1 is a schematic diagram showing a schematic configuration of a film formation apparatus according to an embodiment.

FIG. 2 is a diagram showing a state of a wafer before a substrate holding process according to an embodiment.

FIG. 3 is a diagram showing an outline of a first process according to an embodiment.

FIG. 4 is a diagram showing a state of a bottom surface of a recess in the first process according to an embodiment.

FIG. 5 is a diagram showing a state of the bottom surface of the recess in a second process according to an embodiment.

FIG. 6 is a diagram showing a state of the bottom surface of the recess in a third process according to an embodiment.

FIG. 7 is a timing chart showing a specific example of a behavior pattern of each portion in a film forming process according to an embodiment.

FIG. 8 is a diagram showing a state of the wafer after the film forming process according to an embodiment.

FIG. 9 is a schematic diagram showing a schematic configuration of a film formation apparatus according to a modification of the embodiment.

FIG. 10 is a flowchart showing a processing procedure of the film forming process according to an embodiment.

### DETAILED DESCRIPTION

Hereinafter, embodiments of a film formation method and a film formation apparatus described herein will be described in detail with reference to the accompanying drawings. Further, the present disclosure is not limited to the embodiments described below. In addition, it should be noted that the drawings are schematic, and the relationships between dimensions of respective elements, the ratios of the respective elements, and the like may differ from reality. Also, there may be a case in which the relationship of dimensions and the ratios differ from each other between the drawings.

In the related art, there is known a technique for forming a metal film in a recess formed in a substrate such as a semiconductor wafer (hereinafter, also referred to as a wafer).

However, in the related art, since the metal film is deposited on both a bottom surface and a side surface of the recess, it has been difficult to selectively form the metal film on the bottom surface of the recess.

Therefore, there is a need for a technique that can overcoming the above-mentioned problem and selectively forming a metal film on a bottom surface of a recess formed in a substrate.

### <Outline of Film Formation Apparatus>

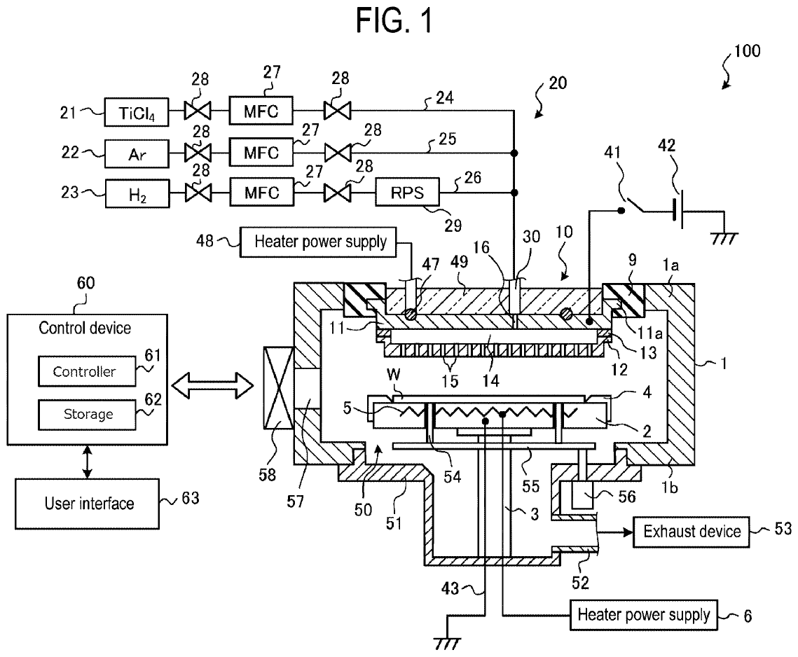

First, a schematic configuration of a film formation apparatus 100 according to an embodiment will be described with reference to FIG. 1. FIG. 1 is a diagram showing the schematic configuration of the film formation apparatus 100 according to the embodiment. The film formation apparatus 100 is, for example, a film formation apparatus for forming a Ti (titanium) film.

The film formation apparatus 100 includes a substantially cylindrical chamber 1. A susceptor 2 is arranged inside the chamber 1 in a state of being supported by a cylindrical support member 3 provided at a lower center of the susceptor 2. The susceptor 2 is a placement table (stage) for horizontally supporting a Si wafer W (hereinafter simply referred to as a wafer W) which is a substrate to be processed, and is made of, for example, a ceramic material such as aluminum nitride (AlN) or the like, or a metallic material such as aluminum or a nickel alloy.

A guide ring 4 for guiding the wafer W is provided on an outer edge portion of the susceptor 2. Further, a heater 5 made of a high-melting-point metal such as molybdenum or the like is embedded in the susceptor 2. The heater 5 is supplied with electric power from a heater power supply 6 to heat the wafer W supported by the susceptor 2 to a predetermined temperature.

A shower head 10 is provided on a top wall 1a of the chamber 1 via an insulating member 9. The shower head 10 is an example of a first electrode. The shower head 10 is a premix-type shower head, and includes a base member 11 and a shower plate 12.

Further, an outer peripheral portion of the shower plate 12 in the shower head 10 is fixed to the base member 11 via an annular intermediate member 13 for preventing sticking.

The shower plate 12 has a flange shape. A recess is formed inside the shower plate 12. That is, a gas diffusion space 14 is formed between the base member 11 and the shower plate 12. A flange portion 11a is formed on an outer peripheral portion of the base member 11. The flange portion 11a is supported by the insulating member 9.

Further, a plurality of gas discharge holes 15 is formed in the shower plate 12. One gas introduction hole 16 is formed in the vicinity of the center of the base member 11. The gas introduction hole 16 is connected to gas lines of a gas supply mechanism 20.

The gas supply mechanism 20 includes a TiCl₄ gas source 21, an Ar gas source 22, and a hydrogen (H₂) gas source 23. The TiCl₄ gas source 21 supplies a TiCl₄ gas, which is a Ti raw material gas.

The Ar gas source 22 supplies an Ar gas used as a plasma generation gas, a purge gas, a carrier gas for the TiCl₄ gas, and the like. The hydrogen gas source 23 supplies a hydrogen gas, which is a reducing gas.

A SiCl₄ gas supply line 24 is connected to the SiCl₄ gas source 21, an Ar gas supply line 25 is connected to the Ar gas source 22, and a hydrogen gas supply line 26 is connected to the hydrogen gas source 23. Each gas line is provided with two valves 28 with a mass flow controller (MFC) 27 interposed therebetween.

Further, the hydrogen gas supply line 26 is provided with a remote plasma source (RPS) 29 further downstream of the valve 28 positioned on the downstream side. The remote plasma source 29 activates the hydrogen gas supplied from the hydrogen gas source 23 with plasma to generate hydrogen radicals.

Further, each gas line is connected to the gas introduction hole 16 via a gas pipe 30. Then, the gases or the hydrogen radicals supplied to the gas introduction hole 16 reach the gas diffusion space 14 via the gas introduction hole 16 and are discharged toward the wafer W inside the chamber 1 via the gas discharge holes 15 of the shower plate 12.

A negative electrode of a DC power supply 42 is connected to the shower head 10 via a switch 41. Further, a positive electrode of the DC power supply 42 is grounded. That is, in an embodiment, a negative bias voltage may be applied from the DC power supply 42 to the shower head 10 by controlling the switch 41 to be turned on. In this way, the shower head 10 also functions as an upper electrode of a parallel plate electrode.

On the other hand, the susceptor 2 functions as a lower electrode of the parallel plate electrode. The susceptor 2 is an example of a second electrode, and is grounded via a transmission line 43.

A heater 47 is provided in the base member 11 of the shower head 10. The heater 47 heats the shower head 10 to a desired temperature by being supplied with electric power from the heater power supply 48. A heat insulating member 49 is provided in a recess formed in an upper portion of the base member 11.

A circular hole 50 is formed in the central portion of a bottom wall 1b of the chamber 1. Further, the bottom wall 1b is provided with an exhaust room 51 projecting downward so as to cover the hole 50. An exhaust pipe 52 is connected to a side surface of the exhaust room 51. An exhaust device 53 is connected to the exhaust pipe 52.

Further, by operating the exhaust device 53, the interior of the chamber 1 may be depressurized to a predetermined degree of vacuum.

The susceptor 2 is provided with a plurality of (e.g., three) wafer support pins 54 for supporting and vertically moving the wafer W. The wafer support pins 54 are provided so as to move upward and downward with respect to a surface of the susceptor 2 and are supported by a support plate 55. The wafer support pins 54 are configured to be raised and lowered via the support plate 55 by a drive mechanism 56.

In a sidewall of the chamber 1, there are provided a loading/unloading port 57 for loading and unloading the wafer W between the chamber 1 and a wafer transfer chamber (not shown) provided adjacent to the chamber 1, and a gate valve 58 for opening and closing the loading/unloading port 57.

Further, the film formation apparatus 100 includes a control device 60. The control device 60 is, for example, a computer, and includes a controller 61 and a storage 62. The storage 62 stores programs that control various processes executed by the film formation apparatus 100. The controller 61 controls the operation of the film formation apparatus 100 by reading and executing the program stored in the storage 62.

The programs may be recorded on a non-transitory computer-readable storage medium, and may be installed from the storage medium on the storage 62 of the control device 60. Examples of the computer-readable storage medium include a hard disk (HD), a flexible disk (FD), a compact disk (CD), a magneto-optical disk (MO), and a memory card.

Further, a user interface 63 including a keyboard for an operator to input commands for managing the film formation apparatus 100, a display for visually displaying the operating status of the film formation apparatus 100, and the like are connected to the control device 60.

### <Details of Film Forming Process>

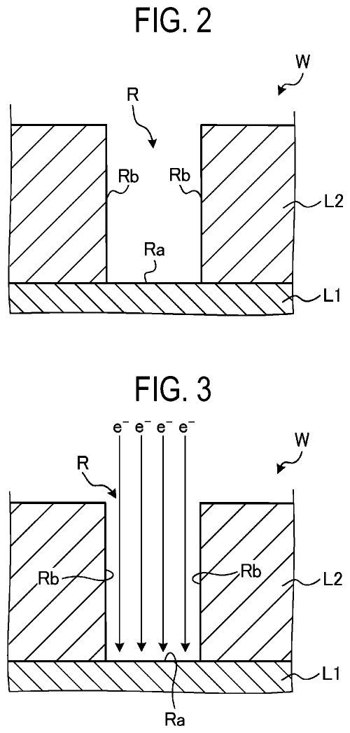

Next, details of a film forming process performed by the film formation apparatus 100 according to an embodiment will be described with reference to FIGS. 2 to 8. In the film forming process according to the embodiment, a substrate holding process is first performed.

First, the controller 61 regulates an internal pressure of the chamber 1 and then opens the gate valve 58 to load the wafer W into the chamber 1 from the transfer chamber (not shown) via the loading/unloading port 57. Subsequently, the controller 61 performs the substrate holding process of holding the wafer W on the susceptor 2 by operating the wafer support pins 54.

Prior to the substrate holding process, a recess R is formed in the surface of the wafer W as shown in FIG. 2. FIG. 2 is a diagram showing a state of the wafer W before the substrate holding process according to the embodiment.

For example, in an embodiment, a dielectric layer L1 and a dielectric layer L2 are laminated in the named order on the surface of the wafer W. The recess R is formed so as to penetrate the dielectric layer L2 positioned on the dielectric layer L1. That is, in the embodiment, the dielectric material is exposed on a bottom surface Ra and a side surface Rb of the recess R.

The dielectric layers L1 and L2 are made of, for example, silicon oxide (SiO₂), silicon nitride (SiN), or the like. In an embodiment, the recess R may be formed inside a single insulator layer, or may be formed so as to penetrate a multilayer film formed of insulator layers.

Following the substrate holding process, a first process is performed by the film formation apparatus 100. Specifically, first, the controller 61 preheats the wafer W while maintaining the interior of the chamber 1 at a predetermined degree of vacuum. Subsequently, when the temperature of the wafer W is substantially stable, the controller 61 performs a pre-flow by allowing an Ar gas, which is a plasma generation gas, to flow from the Ar gas source 22 to a pre-flow line (not shown).

Subsequently, after performing the pre-flow, the controller 61 switches the gas line to the line for film formation while maintaining a gas flow rate and a pressure as they are, whereby the Ar gas is introduced from the Ar gas source 22 into the chamber 1 via the shower head 10.

Subsequently, after the Ar gas is introduced into the chamber 1, the controller 61 applies a negative bias voltage from the DC power supply 42 to the shower head 10 by controlling the switch 41 to be turned on. As a result, a DC electric field is formed between the shower head 10 and the susceptor 2, so that the Ar gas existing between the shower head 10 and the susceptor 2 is plasmarized. Further, electrons (e⁻) generated in the plasma of the Ar gas are irradiated onto the surface of the wafer W.

In the first process according to an embodiment, the susceptor 2 is grounded and the negative bias voltage is applied to the shower head 10. Therefore, as shown in FIG. 3, the generated electrons are irradiated onto the bottom surface Ra of the recess R with high directivity. FIG. 3 is a diagram showing an outline of the first process according to an embodiment.

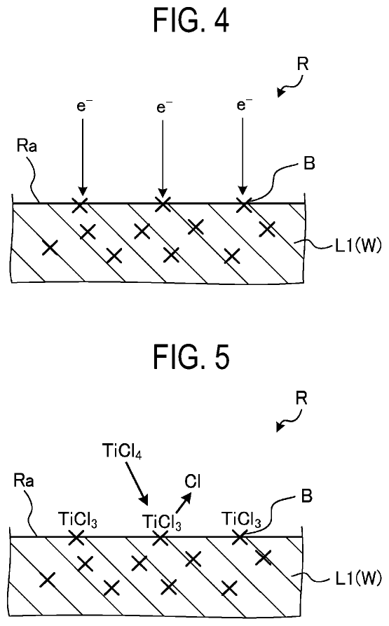

Further, in an embodiment, when the bottom surface Ra of the recess R is irradiated with the electrons, as shown in FIG. 4, dangling bonds B are formed on the surface of the dielectric layer L1 exposed from the bottom surface Ra of the recess R or inside the dielectric layer L1. FIG. 4 is a diagram showing a state of the bottom surface Ra of the recess R in the first process according to an embodiment.

On the other hand, in the first process according to an embodiment, the generated electrons are irradiated onto the recess R with high directivity as shown in FIG. 3. Therefore, the electrons are hardly irradiated onto the side surface Rb of the recess R. Therefore, in the first process according to an embodiment, the dangling bonds B (see FIG. 4) are hardly formed on the side surface Rb of the recess R.

Further, in the first process according to an embodiment, the negative bias voltage is applied to the shower head 10. Therefore, Ar ions (Ar⁺) generated in the plasma are transported toward the shower head 10 and are incident on the shower head 10. As a result, the Ar ions are not irradiated onto the wafer W.

As described above, the first process according to the embodiment is a process of selectively irradiating the bottom surface Ra of the recess R formed on the surface of the wafer W with an electron beam.

Then, the controller 61 terminates the first process according to the embodiment by controlling the switch 41 to be turned off after a predetermined period of time has elapsed from the turning-on of the switch 41. The controller 61 continues to supply the Ar gas into the chamber 1 even after the switch 41 is turned off.

Following the first process described thus far, a second process is performed by the film formation apparatus 100. Specifically, first, the controller 61 performs a pre-flow by allowing a TiCl₄ gas, which is a raw material gas, to flow from the TiCl₄ gas source 21 to a pre-flow line (not shown).

Then, after performing the pre-flow, the controller 61 switches the gas line to the line for film formation while maintaining the gas flow rate and the pressure as they are. The TiCl₄ gas and the Ar gas are introduced into the chamber 1 from the TiCl₄ gas source 21 and the Ar gas source 22 via the shower head 10. At this time, the Ar gas functions as a carrier gas for the TiCl₄ gas.

Then, as shown in FIG. 5, the TiCl₄ gas that has reached the surface of the wafer W is chemically adsorbed on the dangling bonds B formed on the bottom surface Ra of the recess R. FIG. 5 is a diagram showing a state of the bottom surface Ra of the recess R in the second process according to an embodiment.

In the second process according to the embodiment, when the raw material gas (TiCl₄) is adsorbed on the dangling bonds B, one Cl atom is desorbed from the TiCl₄ gas to form TiCl₃, which is then chemically adsorbed on the dangling bond B.

On the other hand, in the second process according to the embodiment, the dangling bonds B are hardly formed on the side surface Rb (see FIG. 2) of the recess R. Therefore, the raw material gas is hardly adsorbed chemically on the side surface Rb.

As described above, the second process according to the embodiment is a process in which the raw material gas is selectively adsorbed chemically on the bottom surface Ra of the recess R formed in the surface of the wafer W.

Then, the controller 61 terminates the second process according to the embodiment by stopping the supply of the raw material gas after a predetermined period of time has elapsed from the start of the supply of the raw material gas. The controller 61 continues to supply the Ar gas into the chamber 1 even after the supply of the raw material gas is stopped. As a result, the controller 61 can perform a purging process inside the chamber 1.

Following the second process and the purging process described thus far, a third process is performed by the film formation apparatus 100. Specifically, first, the controller 61 performs a pre-flow by allowing a hydrogen gas, which is a reducing gas, to flow from the hydrogen gas source 23 to a pre-flow line (not shown). Then, after performing the pre-flow, the controller 61 switches the gas line to the line for film formation and introduces the hydrogen gas from the hydrogen gas source 23 to the remote plasma source 29.

Subsequently, the controller 61 operates the remote plasma source 29 to activate the hydrogen gas inside the remote plasma source 29, thereby generating hydrogen radicals (H·). Then, the controller 61 introduces the hydrogen radicals from the remote plasma source 29 into the chamber 1 via the shower head 10 while maintaining the gas flow rate and the pressure as they are.

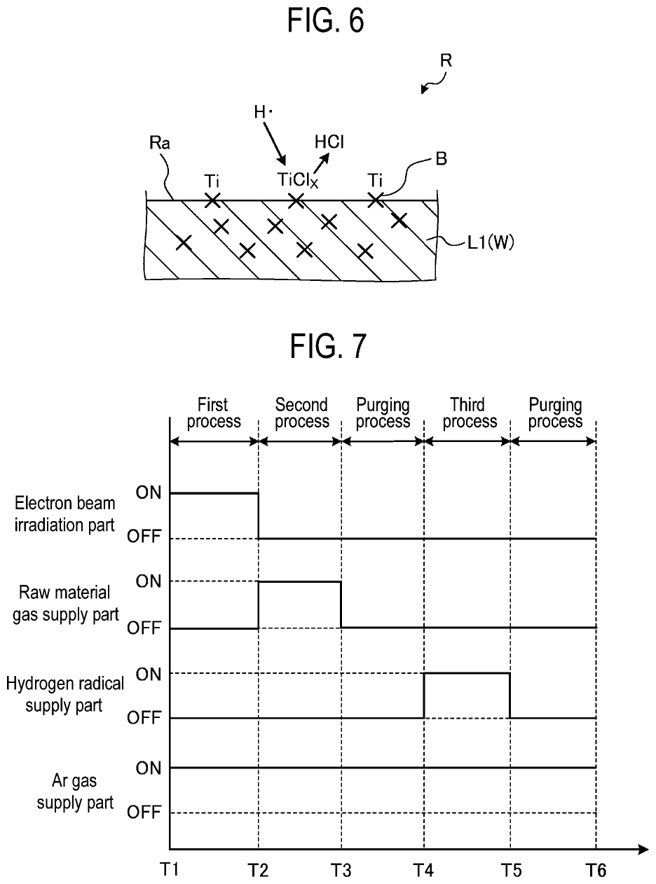

Then, as shown in FIG. 6, the hydrogen radicals that have reached the surface of the wafer W react with the raw material gas chemically adsorbed on the bottom surface Ra of the recess R, and the Cl atoms contained in the raw material gas are desorbed as an HCl gas from the surface of the wafer W. FIG. 6 is a diagram showing a state of the bottom surface Ra of the recess R in the third process according to the embodiment.

As a result, in the third process according to the embodiment, the Cl atoms are desorbed from the raw material gas chemically adsorbed on the dangling bonds B to leave only Ti atoms. Therefore, the Ti atoms can be selectively deposited as an atomic layer on the bottom surface Ra of the recess R.

Then, the controller 61 terminates the third process according to the embodiment by stopping the supply of the hydrogen radicals after a predetermined period of time has elapsed from the start of the supply of the hydrogen radicals. The controller 61 continues to supply the Ar gas into the chamber 1 even after the supply of the hydrogen radicals is stopped. As a result, the controller 61 can perform a purging process inside the chamber 1.

FIG. 7 is a timing chart showing a specific example of a behavior pattern of each part in the film forming process according to the embodiment. As shown in FIG. 7, in the embodiment, the first process, the second process, the purging process, the third process, and the purging process are performed in the named order.

First, the controller 61 (see FIG. 1) operates (turns on) an Ar gas supply part and an electron beam irradiation part from time T1 to start the first process of irradiating the wafer W with the electron beam.

The Ar gas supply part according to an embodiment includes the Ar gas source 22, the mass flow controller 27, the valve 28, and the like, and is configured to supply the Ar gas into the chamber 1. Further, the electron beam irradiation part according to an embodiment is composed of the susceptor 2, the shower head 10, the switch 41, the DC power supply 42, and the like, and is configured to irradiate the wafer W with an electron beam.

Then, at time T2 when a predetermined period of time has elapsed from time T1, the controller 61 stops (turns off) the operation of the electron beam irradiation part. As a result, the first process is completed.

Subsequently, the controller 61 continuously operates the Ar gas supply part, and operates (turns on) a raw material gas supply part from time T2 to start the second process of supplying the raw material gas to the wafer W.

The raw material gas supply part according to an embodiment includes the TiCl₄ gas source 21, the mass flow controller 27, the valve 28, and the like, and is configured to supply the raw material gas (in this case, TiCl₄ gas) into the chamber 1.

Then, at time T3 when a predetermined period of time has elapsed from time T2, the controller 61 stops (turns off) the operation of the raw material gas supply part. As a result, the second process is completed.

Subsequently, the controller 61 performs a purging process of purging the interior of the chamber 1 by continuously operating the Ar gas supply part even after time T3. The purging process is performed until time T4 at which a predetermined period of time has elapsed from time T3.

Subsequently, the controller 61 continuously operates the Ar gas supply part and operates (turns on) a hydrogen radical supply part from time T4 to start the third process of supplying the hydrogen radicals to the wafer W.

The hydrogen radical supply part according to an embodiment includes the hydrogen gas source 23, the mass flow controller 27, the valve 28, the remote plasma source 29, and the like, and is configured to supply the hydrogen radicals into the chamber 1.

Then, at time T5 when a predetermined period of time has elapsed from time T4, the controller 61 stops (turns off) the operation of the hydrogen radical supply part. As a result, the third process is completed.

Subsequently, the controller 61 performs a purging process of purging the interior of the chamber 1 by continuously operating the Ar gas supply part even after time T5. Such a purging process is performed until time T6 at which a predetermined period of time has elapsed from time T5.

By each process described thus far, the controller 61 can selectively form a Ti film on the bottom surface Ra of the recess R formed in the wafer W.

Further, in an embodiment, the first process, the second process, the purging process, the third process, and the purging process shown in FIG. 7 may be sequentially repeated.

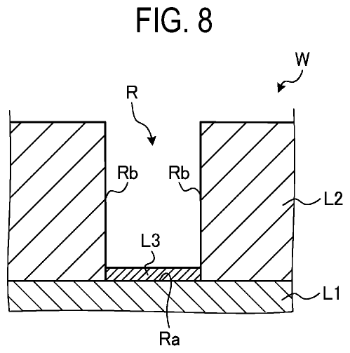

As a result, the island-shaped (discontinuous) Ti film formed on the bottom surface Ra of the recess R may be grown into a uniform (continuous) Ti film. Therefore, as shown in FIG. 8, a Ti metal film L3 may be selectively formed on the bottom surface Ra of the recess R. FIG. 8 is a diagram showing a state of the wafer W after the film forming process according to an embodiment.

The film forming process according to the embodiment is not limited to the case in which the first process, the second process, the purging process, the third process, and the purging process are all sequentially repeated. In some cases, the first process may be omitted.

This is because, due to the steric hindrance of the adsorbed raw material gas molecules, in one round of second process, the entire raw material gas may not be adsorbed to the dangling bonds B formed in one round of first process. Therefore, even if a subsequent round of first process is omitted, the raw material gas may be adsorbed again to the surplus dangling bonds B.

For example, in this case, when the first process, the second process, the purging process, the third process, and the purging process are sequentially repeated in a plurality of cycles, the first process may be omitted once in several cycles.

Further, in an embodiment, the first process of irradiating the wafer W with an electron beam may be performed by applying a DC bias to the shower head 10 arranged to face the wafer W.

As a result, the electron beam can be selectively irradiated onto the wafer W without irradiating the wafer W with Ar ions in the plasma generated between the shower head 10 and the susceptor 2. Further, the wafer W can be irradiated with an electron beam without separately using a dedicated electron beam irradiation means such as an electron gun or the like.

Further, in an embodiment, the first process of irradiating the wafer W with the electron beam is not limited to the case in which the first process is performed only before the second process of chemically adsorbing the raw material gas, and may be additionally performed after the second process. As a result, it is possible to promote the desorption of the Cl atoms contained in the raw material gas chemically adsorbed on the bottom surface Ra of the recess R.

Further, in an embodiment, a dielectric material may be exposed on the bottom surface Ra of the recess R formed in the wafer W. When the dielectric is exposed on the bottom surface Ra of the recess R in this way, the raw material gas is not chemically adsorbed on the bottom surface Ra of the recess R even if the raw material gas is supplied as it is.

On the other hand, in the embodiment, since the dangling bonds B are formed by irradiating the electron beam before supplying the raw material gas, the raw material gas can be satisfactorily chemisorbed on the bottom surface Ra of the recess R.

Therefore, in the embodiment, the metal film L3 can be selectively formed on the bottom surface Ra of the recess R even when the dielectric material is exposed on the bottom surface Ra of the recess R.

Further, in an embodiment, the third process of supplying the hydrogen radicals to the wafer W may be performed using the hydrogen radicals activated by the remote plasma source 29 provided outside the chamber 1.

As a result, it is possible to prevent the wafer W from being irradiated with various ions generated when the hydrogen radicals are generated inside the chamber 1, thereby suppressing formation of dangling bonds B on the side surface Rb of the recess R.

Therefore, according to the embodiment, the metal film L3 can be further selectively formed on the bottom surface Ra of the recess R formed in the wafer W.

In the above embodiment, the example in which the Ti metal film L3 is formed on the bottom surface Ra of the recess R has been described. However, the metal film to be formed is not limited to Ti, but may be formed of W (tungsten), Co (cobalt), Mo (molybdenum), Ta (tantalum), and the like. In this case, a metal halide gas such as WF₆ or WCl₆ may be used as the raw material gas.

### <Modification>

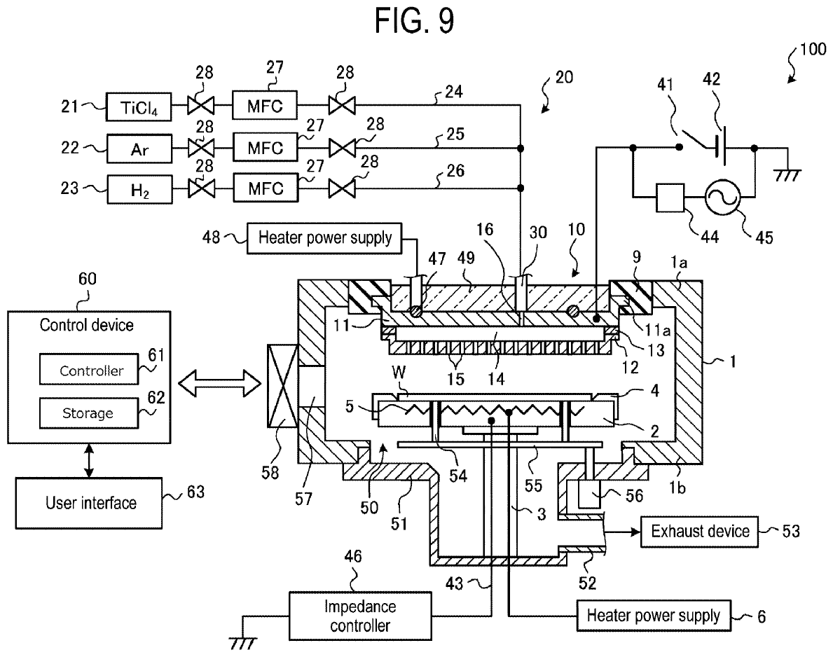

Next, a modification of the embodiment will be described with reference to FIG. 9. In the modification described below, the same parts as those of the embodiment are designated by like reference numerals, and the duplicate description thereof will be omitted.

FIG. 9 is a schematic view showing a schematic configuration of a film formation apparatus 100 according to the modification of the embodiment. As shown in FIG. 9, in the modification, the configuration of the hydrogen radical supply part is different from that of the embodiment.

Specifically, in the modification, the remote plasma source 29 is omitted, and a matcher 44 and a radio frequency power supply 45, which are connected in a parallel relationship with respect to the switch 41 and the DC power supply 42, are provided between the shower head 10 and the ground potential.

Further, in the modification, an impedance controller 46 is provided in a transmission line 43 that connects the susceptor 2 and the ground potential. The impedance controller 46 may be controlled by the controller 61 so as to adjust an impedance of the susceptor 2 to various values.

This modification is similar to the embodiment in that the first process, the second process, the purging process, the third process, and the purging process are performed in the named order. Therefore, in the following, details of a film forming process according to the modification will be described with reference to FIG. 7.

As shown in FIG. 7, first, the controller 61 operates (turns on) the Ar gas supply part and the electron beam irradiation part from time T1 to start the first process of irradiating the wafer W with the electron beam. Since an Ar gas supply part and an electron beam irradiation part according to the modification are similar to those of the embodiment, the detailed description thereof will be omitted.

Then, at time T2 when a predetermined period of time has elapsed from time T1, the controller 61 stops (turns off) the operation of the electron beam irradiation part. As a result, the first process is completed.

Subsequently, the controller 61 continuously operates the Ar gas supply part, and operates (turns on) the raw material gas supply part from time T2 to start the second process of supplying the raw material gas to the wafer W. Since the raw material gas supply part according to the modification is similar to that of the embodiment, the detailed description thereof will be omitted.

Then, at time T3 when a predetermined period of time has elapsed from time T2, the controller 61 stops (turns off) the operation of the raw material gas supply part. As a result, the second process is completed.

Subsequently, the controller 61 performs a purging process of purging the interior of the chamber 1 by continuously operating the Ar gas supply part even after time T3. The purging process is performed until time T4 at which a predetermined period of time has elapsed from time T3.

Subsequently, the controller 61 continuously operates the Ar gas supply part and operates (turns on) the hydrogen radical supply part from time T4 to start the third process of supplying the hydrogen radicals to the wafer W.

As shown in FIG. 9, the hydrogen radical generation part according to the modification includes the susceptor 2, the shower head 10, the hydrogen gas source 23, the mass flow controller 27, the valve 28, the matcher 44, the radio frequency power supply 45, the impedance controller 46, and the like. Then, the hydrogen radical generation part according to the modification supplies hydrogen radicals into the chamber 1.

In the third process according to the modification, first, the controller 61 operates the mass flow controller 27 and the valve 28 to introduce a hydrogen gas from the hydrogen gas source 23 into the chamber 1 via the shower head 10. At this time, the Ar gas is continuously supplied from the Ar gas source 22 into the chamber 1.

Subsequently, the controller 61 operates the radio frequency power supply 45 to supply radio frequency power to the shower head 10. As a result, a radio frequency electric field is formed between the shower head 10 and the susceptor 2, whereby the hydrogen gas and the Ar gas existing between the shower head 10 and the susceptor 2 are plasmarized.

A frequency of the radio frequency power supplied from the radio frequency power supply 45 may be set to 200 kHz to 60 MHz.

Further, the controller 61 controls the impedance controller 46 at the same timing as that at which the radio frequency power supply 45 is operated, to adjust the impedance so that the susceptor 2 has a high impedance.

As a result, the hydrogen radicals generated in the plasma are supplied to the wafer W, while the various ions generated in the plasma are hindered from approaching the susceptor 2 having a high impedance.

That is, in the modification, the hydrogen radicals generated in the plasma can be sufficiently supplied into the recess R of the wafer W, and an incident energy when various ions generated in the plasma are incident on the wafer W can be reduced.

Therefore, according to the modification, it is possible to suppress the formation of the dangling bonds B on the side surface Rb of the recess R due to the incidence of various ions generated in the plasma. Since the hydrogen radicals are supplied, the metal film L3 can be selectively formed on the bottom surface Ra of the recess R formed in the wafer W.

In the modification, there has been described the example in which the impedance is adjusted by the impedance controller 46 so that the susceptor 2 has a high impedance. However, the susceptor 2 may be made to have a high impedance by keeping the susceptor 2 in a floating state.

As described above, the remote plasma source 29 is not required in the modification. This makes it possible to simplify the configuration of the film formation apparatus 100, and thus reduce the manufacturing cost of the film formation apparatus 100.

Returning to the description of FIG. 7, at time T5 when a predetermined period of time has elapsed from time T4, the controller 61 stops (turns off) the operation of the hydrogen radical supply part. As a result, the third process is completed.

Subsequently, the controller 61 performs a purging process of purging the interior of the chamber 1 by continuously operating the Ar gas supply part even after time T5. Such a purging process is performed until time T6 at which a predetermined period of time has elapsed from time T5.

By each process described thus far, the controller 61 can selectively form a Ti film on the bottom surface Ra of the recess R formed in the wafer W.

In the above modification, there has been described the example in which the remote plasma source 29 is omitted. However, the remote plasma source 29 may be added to the hydrogen radical generation part according to the modification. This makes it possible to apply a larger amount of hydrogen radicals to the wafer W. Therefore, it is possible to improve the film formation efficiency of the Ti film.

The film formation apparatus 100 according to the embodiment includes the electron beam irradiation part, the raw material gas supply part, the hydrogen radical supply part, and the controller 61. The electron beam irradiation part irradiates the substrate (wafer W) with an electron beam. The raw material gas supply part supplies the raw material gas to the substrate (wafer W). The hydrogen radical supply part supplies the hydrogen radicals to the substrate (wafer W). The controller 61 controls each part. Further, the controller 61 causes the electron beam irradiation part to irradiate the substrate (wafer W) having the recess R formed therein with the electron beam, and causes the raw material gas supply part to supply the raw material gas to the substrate (wafer W), thereby allowing the raw material gas to be adsorbed on the bottom surface Ra of the recess R. Further, the controller 61 causes the hydrogen radical supply part to supply the hydrogen radicals to the substrate (wafer W) so that the raw material gas adsorbed on the bottom surface Ra of the recess R reacts with the hydrogen radicals. As a result, the metal film L3 can be selectively formed on the bottom surface Ra of the recess R formed in the wafer W.

### <Process Procedure>

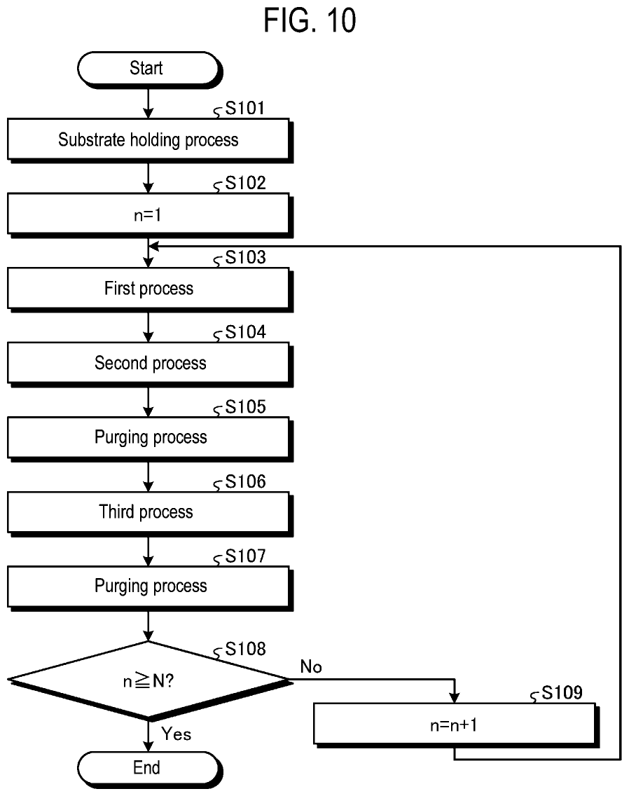

Next, a procedure of the film forming process according to an embodiment will be described with reference to FIG. 10. FIG. 10 is a flowchart showing the procedure of the film forming process executed by the film formation apparatus 100 according to the embodiment.

First, the controller 61 controls the wafer support pins 54 and the like to perform a substrate holding process for causing the susceptor 2 to hold the wafer W (step S101). Then, the controller 61 sets a counter n for counting the number of repetitions of the film forming process to 1 (step S102).

Subsequently, the controller 61 controls the Ar gas supply part, the electron beam irradiation part, and the like to perform the first process of irradiating the wafer W with the electron beam (step S103). Then, the controller 61 controls the raw material gas supply part and the like to perform the second process of supplying the raw material gas to the wafer W (step S104).

Subsequently, the controller 61 controls the Ar gas supply part and the like to perform the purging process of purging the interior of the chamber 1 with the Ar gas (step S105). Then, the controller 61 controls the hydrogen radical supply part and the like to perform the third process of supplying the hydrogen radicals to the wafer W (step S106).

Subsequently, the controller 61 controls the Ar gas supply part and the like to perform the purging process of purging the interior of the chamber 1 with the Ar gas (step S107). Then, the controller 61 determines whether or not the counter n is equal to or greater than a predetermined number of times N (step S108). Information about the predetermined number of times N is stored in advance in the storage 62.

Subsequently, when the counter n is equal to or greater than the predetermined number of times N (“Yes,” in step S108), the controller 61 terminates the process.

On the other hand, when the counter n is not equal to or greater than the predetermined number of times N (“No,” in step S108), the controller 61 increments the counter n for counting the number of repetitions of the film forming process (step S109), and returns to step S103.

The film formation method according to the embodiment includes a first step (step S103), a second step (step S104), and a third step (step S106). In the first step (step S103), the substrate (wafer W) on which the recess R is formed is irradiated with the electron beam. In the second step (step S104), the raw material gas is supplied to the substrate (wafer W), and the raw material gas is adsorbed on the bottom surface Ra of the recess R. In the third step, the hydrogen radicals are supplied to the substrate (wafer W) so that the raw material gas adsorbed on the bottom surface Ra of the recess R reacts with the hydrogen radicals. As a result, the metal film L3 can be selectively formed on the bottom surface Ra of the recess R formed in the wafer W.

Further, in the film formation method according to the embodiment, the first step (step S103) is performed by applying a DC bias to the first electrode (shower head 10) arranged to face the substrate (the wafer W). As a result, the electron beam can be selectively irradiated onto the wafer W without irradiating the wafer W with the Ar ions inside the chamber 1.

Further, in the film formation method according to the embodiment, the second step (step S104) is performed after the first step (step S103). Further, in the second step (step S104), the raw material gas is selectively adsorbed on the bottom surface Ra of the recess R irradiated with the electron beam. As a result, the metal film L3 can be selectively formed on the bottom surface Ra of the recess R formed in the wafer W.

Further, in the film formation method according to the embodiment, the dielectric material is exposed on the bottom surface Ra of the recess R. As a result, the metal film L3 can be selectively formed on the bottom surface Ra of the recess R from which the dielectric material is exposed.

Further, in the film formation method according to the embodiment, the raw material gas is a metal halide gas. As a result, the raw material gas can be selectively adsorbed on the bottom surface Ra of the recess R irradiated with the electron beam.

Further, in the film formation method according to the embodiment, the respective steps from the first step (step S103) to the third step (step S106) are sequentially repeated. As a result, the island-shaped (discontinuous) Ti film formed on the bottom surface Ra of the recess R can be grown into a uniform (continuous) Ti film.

Further, in the film formation method according to the embodiment, the respective steps from the first step (step S103) to the third step (step S106) are sequentially repeated. In such a sequential repetition, the first process (step S103) is omitted once in several cycles. As a result, the film forming process can be partially omitted. This makes it possible to shorten the time required for forming the metal film L3.

Further, in the film formation method according to the embodiment, the third step (step S106) is performed by supplying the hydrogen radicals activated by the remote plasma source 29 to the substrate (wafer W). As a result, the metal film L3 can be more selectively formed on the bottom surface Ra of the recess R formed in the wafer W.

Further, in the film formation method according to the embodiment, the third step (step S106) is performed such that the hydrogen radicals activated by applying a radio frequency to the first electrode (shower head 10) arranged to face the substrate (wafer W) are supplied to the substrate (wafer W), and the second electrode (susceptor 2) adjacent to the substrate (wafer W) has a high impedance. As a result, the metal film L3 can be selectively formed on the bottom surface Ra of the recess R formed in the wafer W.

Although the embodiments of the present disclosure have been described above, the present disclosure is not limited to the above-described embodiments, and various changes may be made without departing from the spirit of the present disclosure. For example, in the above-described embodiments, the example in which the wafer W is irradiated with the electron beam by applying the DC bias to the shower head 10 has been described. However, the electron beam may be irradiated onto the wafer W by using various electron generation means such as an electron gun or the like.

It should be noted that the embodiments disclosed herein are exemplary and not limitative in all respects. Indeed, the above-described embodiments can be embodied in a variety of forms. Moreover, the above-described embodiments may be omitted, replaced, or changed in various forms without departing from the scope of the appended claims and the purpose thereof.

### EXPLANATION OF REFERENCE NUMERALS

W: wafer (an example of substrate), R: recess, Ra: bottom surface, 2: susceptor (an example of second electrode), 10: shower head (an example of first electrode), 29: remote plasma source, 61: controller, 100: film formation apparatus

What is claimed is:

1. A substrate processing method, comprising:
(a) placing a substrate on a stage, which is grounded, in a processing container;
(b) supplying a plasma generation gas into the processing container via a shower head as a first electrode arranged to face the stage;
(c) applying a negative DC bias from a DC power supply to the first electrode to form a DC electric field to thereby generate a plasma between the shower head and the stage, wherein ions and electrons are generated in the plasma; and
(d) exposing the substrate to the plasma, wherein the ions in the plasma being not irradiated onto the substrate by being attracted to the shower head and the electrons in the plasma being irradiated onto a surface of the substrate occur simultaneously,
wherein (a), (b), (c) and (d) are sequentially performed.

2. The substrate processing method of claim 1, wherein the substrate has at least one recess thereon, and
wherein in (d), the electrons are not irradiated onto a side surface of the at least one recess, and are selectively irradiated onto a bottom surface of the at least one recess.

3. The substrate processing method of claim 2, wherein a dielectric layer is exposed at the bottom surface of the at least one recess, and
wherein in (d), dangling bonds are formed inside the dielectric layer or on a surface of the dielectric layer exposed at the bottom surface, by the selective irradiation of the electrons.

4. The substrate processing method of claim 1, wherein the plasma generation gas is argon gas.

5. The substrate processing method of claim 3, further comprising:
(e) after (d), supplying a metal halide gas into the processing container to expose the substrate to the metal halide gas so that the metal halide gas is selectively chemically adsorbed on the dangling bonds formed in (d); and
(f) supplying hydrogen radicals to the substrate to cause reaction of the hydrogen radicals with the chemically adsorbed metal halide gas so that a metal film is formed selectively on the bottom surface of the at least one recess.

6. The substrate processing method of claim 5, wherein the hydrogen radicals are generated by being activated by a remote plasma source.

7. The substrate processing method of claim 5, wherein the hydrogen radicals are generated by adjusting an impedance of a second electrode of the stage so that the second electrode has an impedance in which the hydrogen radicals are propelled to a surface of the substrate, while the hydrogen radicals, activated by applying a radio frequency to the first electrode arranged to face the stage, are supplied to the substrate.

8. The substrate processing method of claim 7, wherein the adjusting the impedance of the second electrode so that the second electrode has the impedance is controlled by an impedance controller connected to the stage.

9. The substrate processing method of claim 7, wherein adjusting the impedance of the second electrode so that the second electrode has the impedance is controlled by keeping the stage in a floating state.

10. The substrate processing method of claim 5, wherein the metal film is one of titanium, tungsten, cobalt, molybdenum, and tantalum.

11. The substrate processing method of claim 5, wherein (a) to (d) are a first process, (e) is a second process, and (f) is a third process, and
herein the first process, the second process, and the third process are sequentially repeated in this order a plurality of times.

12. The substrate processing method of claim 11, wherein the respective processes from the first process to the third process are sequentially repeated, and when the processes are sequentially repeated, the first process is omitted once in at least two cycles.

13. The substrate processing method of claim 11, further comprising a purging process of purging an interior of the processing container between the second process and the third process, and between the third process and the first process.
